(19) United States
(12) Patent Application Publication
(10) Pub. No.: US 2012/0225538 A1
(43) Pub. Date: Sep. 6, 2012

(54) METHODS OF DISPOSING ALIGNMENT KEYS AND METHODS OF FABRICATING SEMICONDUCTOR CHIPS USING THE SAME

(76) Inventors: Minjung Kim, Yongin-si (KR); Inho Nam, Suwon-si (KR); Jaepil Lee, Hwaseong-si (KR)

(21) Appl. No.: 13/407,136

(22) Filed: Feb. 28, 2012

(30) Foreign Application Priority Data
Mar. 3, 2011 (KR) 10-2011-0019017

(51) Int. Cl. H01L 21/78; H01L 21/306

(52) U.S. Cl. 438/462; 438/708; 257/E21.599; 257/E21.215

(57) ABSTRACT

A method of disposing alignment keys may include preparing a substrate including a shot group which includes a plurality of chip regions, and each of chip regions includes a key region. The method further includes forming at least one alignment key in each of the key regions of the substrate. Each of the alignment keys may be adapted to be used for at least one of a plurality of exposure processes which may be different from each other, and center points of the key regions may be located at points shifted from center points of the chip regions by the same distance along the same direction.

### CROSS-REFERENCE TO RELATED APPLICATIONS

This U.S. non-provisional patent application claims priority under 35 U.S.C.§119 to Korean Patent Application No. 10-2011-0019017, filed on Mar. 03, 2011, the disclosure of which is hereby incorporated by reference herein in it's entirety.

### BACKGROUND OF THE INVENTION

Embodiments of the inventive concepts relate generally to methods of disposing alignment keys and methods of fabricating semiconductor chips using the same.

In the electronic industry in technologies such as, for example, mobile phones or laptop computers, electronic devices having the following features of light weight, a small form factor, high speed, multifunction, high performance, high reliability and/or low cost may be required. To satisfy the above requirements, semiconductor devices with high integration density have been extensively studied.

In particular, a variety of semiconductor chip lay-out structures have been proposed to increase an area efficiency of a wafer. In other words, a variety of research has been ongoing to obtain more semiconductor chips from a wafer.

### SUMMARY

Embodiments of the inventive concepts provide disposing methods of alignment keys.

Embodiments of the inventive concepts provide fabrication methods of semiconductor chips capable of providing higher productivity.

According to an example embodiment of the inventive concept, a method of disposing alignment keys is provided. The method may include preparing a substrate including a shot group which includes a plurality of chip regions, and each of chip regions includes a key region. The method further includes forming at least one alignment key in each of the key regions of the substrate. Each of the alignment keys is adapted to be used for at least one of a plurality of exposure processes which may be different from each other, and center points of the key regions may be located at points shifted from center points of the chip regions by the same distance along the same direction.

In an embodiment, the key regions in the shot group have the substantially same area as each other.

In an embodiment, the alignment keys disposed in the key regions have the substantially same width in a specific direction.

In an embodiment, the forming of the alignment key further includes forming a scribe lane between the chip regions.

In an embodiment, in the specific direction, a width of the scribe lane may be less than a shortest width of the alignment key.

According to an example embodiment of the inventive concept, a method of fabricating a semiconductor chip may be provided. The method may include preparing a wafer including a shot group which includes a plurality of chip regions, and each of the chip regions includes a key region. The method further forming at least one alignment key in each of the key regions of the substrate, and performing a plurality of exposure processes on the shot group to form semiconductor devices on the chip regions. Each of the exposure processes may be performed using one of the alignment keys formed in the key regions of the shot group.

In an embodiment, the plurality of the chip regions may be defined by a scribe lane.

In an embodiment, in a specific direction, a width of the scribe lane may be less than a shortest width of the alignment key.

In an embodiment, the method may further include dicing the wafer to separate the chip regions from each other. The dicing of the wafer is performed between the chip regions adjacent to each other.

In an embodiment, the dicing of the wafer may be performed using a laser.

In an embodiment, the key regions included in the chip regions have the substantially same area as each other.

In an embodiment, center points of the key regions may be located at points shifted from center points of the chip regions by the same distance along the same direction.

According to an example embodiment of the inventive concept, a method of fabricating a semiconductor chip is provided. The method includes preparing a wafer including a shot group which includes a first chip region, a second chip region, a third chip region, a fourth chip region, a fifth chip region, and a sixth chip region disposed in two rows and three columns. The first to sixth chip regions each include a key region. Center points of the key regions are located at points shifted from center points of the first to sixth chip regions by a same distance and along a same direction. The method further includes forming at least one alignment key in a respective one of each of the key regions of the first to sixth chip regions, performing a plurality of exposure processes on the shot group to form semiconductor devices on the first to sixth chip regions, and each of the exposure processes is performed using one of the alignment keys formed in the key regions of the shot group and at least two of the exposure processes are performed using a same one of the alignments keys. The method further includes forming a scribe lane between each of the first to sixth chips regions. The scribe lane has a width less than a first directional width or a second directional width of at least one of the alignment keys.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a wafer including shot groups according to an example embodiment of the inventive concept;

FIG. 2 is a plan view illustrating a shot group according to an example embodiment of the inventive concept;

FIG. 3 represents a coordinate system provided for explaining relative positions of key regions in chip regions according to an example embodiment of the inventive concept;

FIGS. 4A through 4F are plan views illustrating a method of disposing alignment keys in a shot group according to an example embodiment of the inventive concept; and

FIG. 5 is a flow chart illustrating an exposure process using alignment keys according to an example embodiment of the inventive concept.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to example embodiments set forth herein. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. Like numbers indicate like elements throughout. As used herein the term “and/or” includes any and all combinations of one or more of the associated listed items.

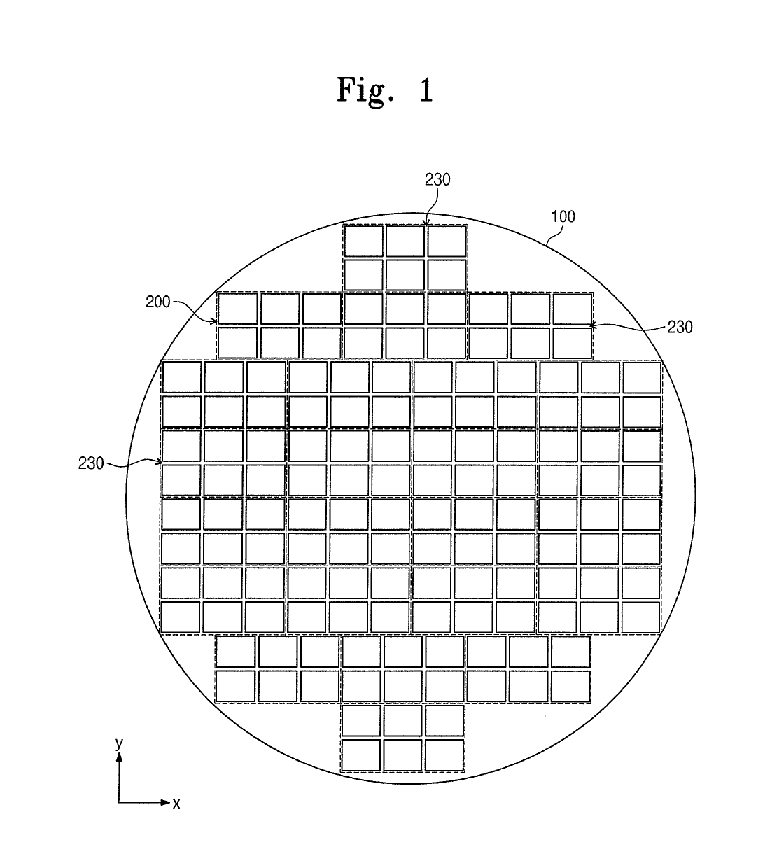

Hereinafter, methods of disposing alignment keys will be described with reference to FIGS. 1 through 3 and FIGS. 4A through 4F.

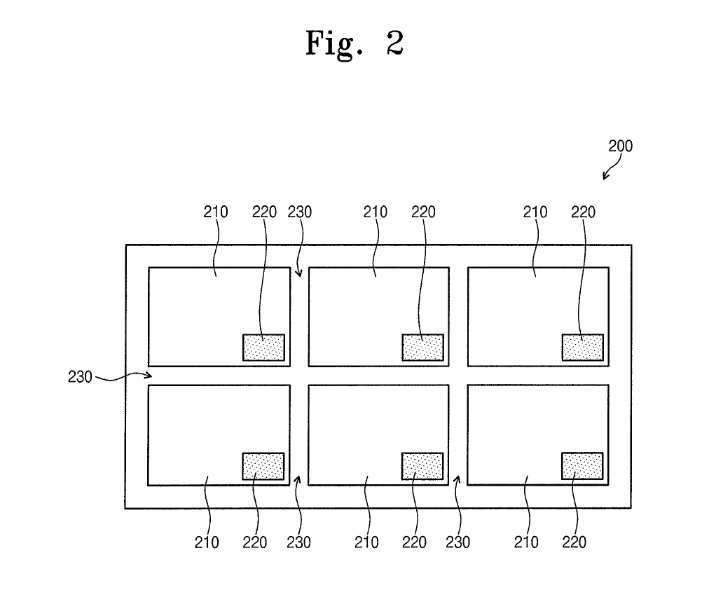

FIG. 1 is a plan view illustrating a wafer including shot groups according to an example embodiment of the inventive concept, and FIG. 2 is a plan view illustrating a shot group according to an example embodiment of the inventive concept.

Referring to FIGS. 1 and 2, a wafer 100 may include, for example, a plurality of shot groups 200. The shot groups 200 may be successively disposed on the wafer 100 along a first direction and a second direction. For example, in some embodiments, the first direction may be parallel to an x-axis, and the second direction may be parallel to a y-axis, which may be perpendicular to the first direction or the x-direction.

Each of the shot groups 200 may include, for example, a plurality of chip regions 210. The chip regions 210 of the shot groups 200 may be disposed in rows and columns. Each of the rows of the chip regions 210 may be, for example, parallel to the first direction, and each of the columns of the chip regions 210 may be, for example, parallel to the second direction. The number of the chip regions 210 included in each of the shot groups 200 may be variously selected. In some embodiments, each of the shot groups 200 may include, for example, six chip regions disposed into two rows and three columns as shown in FIGS. 1 and 2, but example embodiments of the inventive concepts may not be limited thereto.

A chip fabricating process may be performed to form semiconductor devices, each of which is integrated on the corresponding one of the chip regions 210. As a result, electric components constituting the semiconductor device, such as, for example, transistors and capacitors, may be formed on the chip regions 210. The semiconductor device integrated on each of the chip regions 210 may correspond to a semiconductor chip.

A scribe lane 230 may be disposed between the chip regions 210. The scribe lane 230 may include, for example, first lanes extending parallel to the first direction and second lanes extending parallel to the second direction. A second directional width of the first lane may be the substantially the same as a first directional width of the second lane, but example embodiments of the inventive concepts may not be limited thereto. The first and second lanes of the scribe lane 230 may be formed, for example, to intersect each other, and thus, the chip regions 210 of the shot groups 200 may have boundaries defined by the scribe lane 230.

The scribe lane 230 may also be formed between adjacent ones of the shot groups 200. In some embodiments, there may be the plurality of the shot groups 200 defined by the scribe lane 230 in the wafer 100.

After the semiconductor devices are integrated on the chip regions 210, the wafer 100 may be diced along the scribe lanes 230 to form a plurality of semiconductor chips. The dicing of the wafer 100 may be performed using, for example, a blade or a laser. The width of the scribe lane 230 can be decreased when using the laser, in comparison to using the blade.

Key regions 220 may be provided on the chip regions 210 of the shot groups 200, respectively. In some embodiments, the key regions 220 provided on the chip regions 210 may be formed to have, for example, substantially the same area as each other.

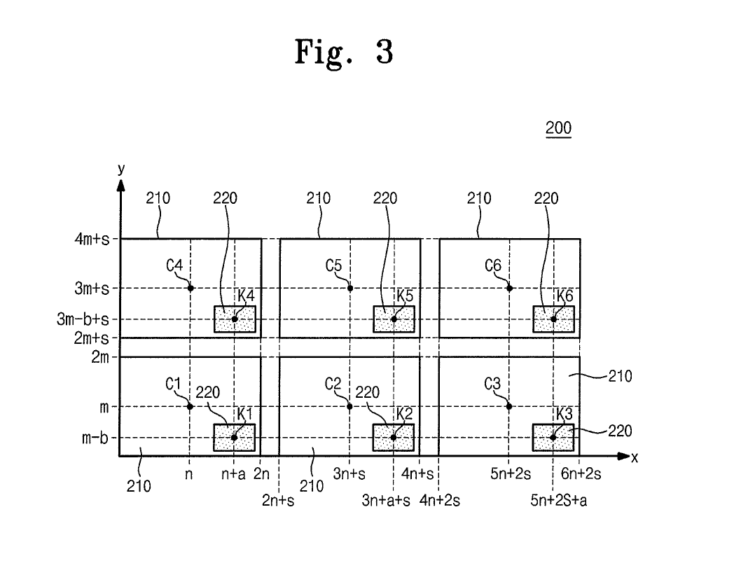

In some embodiments, the key regions 220 may be disposed at the same position in the respective chip regions. Hereinafter, positions of the key regions 220 relative to the chip regions 210 will be described in further detail with reference to FIG. 3. FIG. 3 represents a coordinate system provided for explaining relative positions of the key regions 220 in the chip regions 210 according to an example embodiment of the inventive concept.

Referring to FIG. 3, to reduce the complexity in the drawings and to provide better understanding of an example embodiment of the inventive concept, each of the shot groups 200 will be assumed to include, for example, six chip regions 210, which will be described hereinafter as first to sixth chip regions 210, respectively. The first chip region 210 may have, for example, a center point C1 located at a point (n, m) in the coordinate system of FIG. 3, where n may be half of the x-directional width of the chip region 210 and m may be half of the y-directional width of the chip region 210. The second chip region 210 may have, for example, a center point C2 located at a point (3n+s, m), where s may be a width of the scribe lane 230. In the coordinate system of FIG. 3, the third chip region 210 may have, for example, a center point C3 located at a point (5n+2s, m), the fourth chip region 210 may have, for example, a center point C4 located at a point (n, 3m+s), the fifth chip region 210 may have, for example, a center point C5 located at a point (3n+s, 3m+s), and the sixth chip region 210 may have, for example, a center point C6 located at a point (5n+2s, 3m+s). The center points C1, C2 and C3 of the first to third chip regions 210 may be spaced apart from each other by the interval of, for example, 2n+s along the x-axis direction. The center points C4, C5 and C6 of the fourth to sixth chip regions 210 may be spaced apart from the center points C1, C2 and C3, respectively, of the first to third chip regions 210 by the interval of, for example, 2m+s along the y-axis and spaced apart from each other by the interval of, for example, 2n+s along the x-axis direction.

Each of the shot groups 200 may include, for example, six key regions 220, which will be described hereinafter as first to sixth key regions 220, respectively. The first to sixth key regions 220 may be disposed in the first to sixth chip regions 210, respectively. The first key region 220 may have, for example, a center point K1 located at a point (n+a, m−b) in the coordinate system of FIG. 3, where a and b may be x- and y-directional distances from the center point C1 of the first chip region to the center point K1 of the first key region 220, respectively. In the coordinate system of FIG. 3, the second key region 220 may have, for example, a center point K2 located at a point (3n+a+s, m−b), the third key region 220 may have, for example, a center point K3 located at a point (5n+2s+a, m−b), the fourth key region 220 may have, for example, a center point K4 located at a point (n+a, 3m−b+s), the fifth key region 220 may have, for example, a center point K5 located at a point (3n+a+s, 3m−b+s), and the sixth key region 220 may have, for example, a center point K6 located at a point (5n+2s+a, 3m−b+s).

According to the aforementioned configuration of the key regions 220 relative to the chip regions 210, the center point K1 of the first key region 220 may be located, for example, at a position shifted by a distance a along the x-axis and by a distance −b along the y-axis, from the center point C1 of the first chip region 210.

The coordinates of the center point K2 of the second key region 220 and the center point C2 of the second chip region 210 are given by (3n+a+s, m−b) and (3n+s, m), respectively. Therefore, the center point K2 of the second key region 220 may be located at, for example, a position shifted by a distance a along the x-axis and by a distance −b along the y-axis, from the center point C2 of the second chip region 210.

The coordinates of the center point K3 of the third key region 220 and the center point C3 of the third chip region 210 are given by (5n+2s+a, m−b) and (5n+2s, m), respectively. Therefore, the center point K3 of the third key region 220 may be located at a position shifted by, for example, a distance a along the x-axis and by a distance −b along the y-axis, from the center point C3 of the third chip region 210.

The coordinates of the center point K4 of the fourth key region 220 and the center point C4 of the fourth chip region 210 are given by (n+a, 3m−b+s) and (n, 3m+s), respectively. Therefore, the center point K4 of the fourth key region 220 may be located at a position shifted by, for example, a distance a along the x-axis and by a distance −b along the y-axis, from the center point C4 of the fourth chip region 210.

The coordinates of the center point K5 of the fifth key region 220 and the center point C5 of the fifth chip region 210 are given by, for example, (3n+a+s, 3m−b+s) and (3n+s, 3m+s), respectively. Therefore, the center point K5 of the fifth key region 220 may be located at a position shifted by a distance a along the x-axis and by, for example, a distance −b along the y-axis, from the center point C5 of the fifth chip region 210.

The coordinates of the center point K6 of the sixth key region 220 and the center point C6 of the sixth chip region 210 are given by, for example, (5n+2s+a, 3m−b+s) and (5n+2s, 3m+s), respectively. Therefore, the center point K6 of the sixth key region 220 may be located at a position shifted by, for example, a distance a along the x-axis and by a distance −b along the y-axis, from the center point C6 of the sixth chip region 210.

As described above, the center points K1 to K6 of the key regions 220 may be located at positions shifted by a distance a along the x-axis and by a distance −b along the y-axis, from the center points C1 to C6 of the chip regions 210, respectively. In other words, the center points K1 to K6 of the key regions 220 may be located at positions shifted from the center points C1 to C6 of the chip regions 210, respectively, by the same displacement vector or by the same distance along the same direction. Accordingly, each of the key regions 220 may be located at the same position relative to the corresponding one of the chip regions 210.

At least one alignment key may be disposed on each of the key regions 220. For instance, one alignment key may be disposed on each of the key regions 220, or a plurality of alignment keys may be disposed on each of the key regions 220.

The alignment key may be used as a fiducial or reference mark for a lithographic process, which may be included as part of the chip fabricating process. For example, the chip fabricating process may include a plurality of lithographic processes, and each of the lithographic processes includes an exposure step and/or an alignment step using the alignment key as the fiducial mark. In some embodiments, the shot group 200 may be configured to include all alignment keys that are used for the plurality of the lithographic processes included in the chip fabricating process. In some cases, some of the alignment keys are used for a plurality of exposure steps in common, and thus the number of alignment keys included in the shot group 200 may be reduced, compared with the absence of such common alignment key.

For instance, let us assume that the chip fabricating process includes first to tenth exposure steps, each of which is performed using an individual alignment key, except for the fourth and eighth exposure steps performed using the same alignment keys as the first and third exposure steps, respectively. In this case, the shot group 200 may be configured to include eight alignment keys.

In some embodiments, all of the alignment keys to be used for the chip fabricating process may be disposed on the key regions 220 in each of the chip regions 210. For instance, at least one of the alignment keys may be disposed on at least one of the key regions 220 in each of the shot groups 200 and each of the key regions 220 may include at least one of the alignment keys; in other words, the alignment keys in each of the shot groups 200 are distributed on plural chip regions 210. The manner of disposing the alignment keys on the key regions 220 may be decided in consideration of occupying areas of the alignment keys. For instance, as all the key regions 220 may have the same occupying area as each other, the larger an occupying area of the alignment key, the smaller the number of the alignment keys which may be disposed in each of the key regions 220.

In some embodiments, a second directional width of the alignment keys may be smaller than the width of the scribe lane 230. The scribe lane 230 may be a region on which a sawing process will be performed to divide the chip regions 210 from each other after the semiconductor devices are integrated on the chip regions 210, respectively. In this sense, reducing an occupying area of the scribe lane 230 may enable the formation of more chip regions 210 in the wafer 100. A way of reducing the width of the scribe lane 230 may be adopted to reduce an occupying area of the scribe lane 230. If the alignment keys are not disposed in the key regions 220, the alignment keys may need to be disposed in the scribe lane 230. In this case, the scribe lane 230 may need to have a width greater than a first directional or second directional width of the alignment key. According to an example embodiment of the inventive concept, as the alignment keys may be disposed in the chip regions 210, the scribe lane 230 can be formed to have a width less than a first directional or second directional width of the alignment key, and moreover, it is possible to reduce an occupying area of the scribe lane 230 in the wafer 100. As a result, it is possible to increase the number of the chip regions 210 that can be formed in the wafer 100.

In some embodiments, all the alignment keys may have the same second directional width as each other, while they may differ from each other in terms of a first directional width. Furthermore, a plurality of the alignment keys may be formed in each of the key regions 220, and in this case, the alignment keys may be arranged along the second direction.

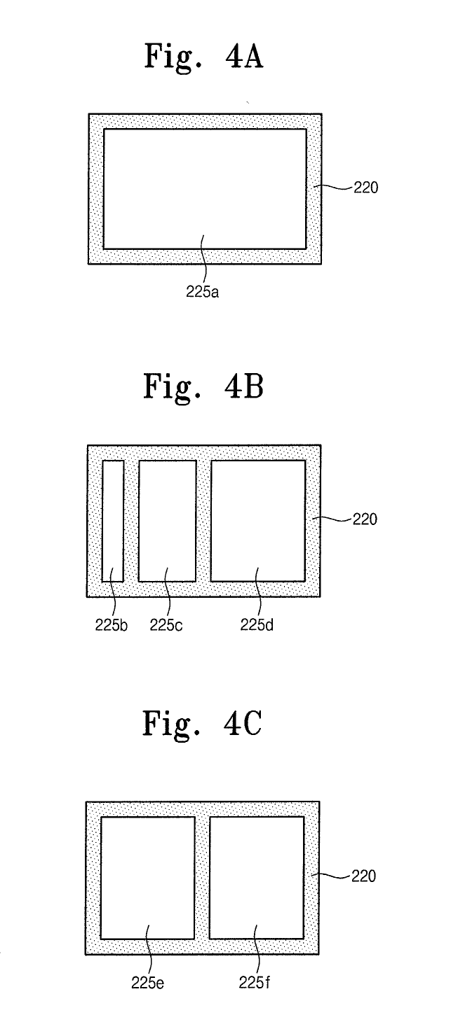

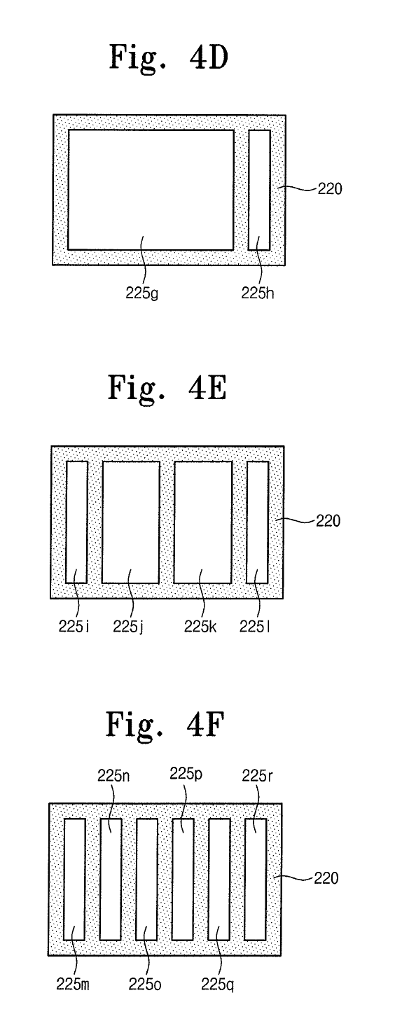

FIGS. 4A through 4F are plan views illustrating a method of disposing alignment keys on the key regions 220 according to an example embodiment of the inventive concept.

For example, as shown in FIG. 4A, one alignment key 225a may be disposed on one of the key regions 220. The alignment key 225a may occupy a large portion of the total area of the key region 220. In some embodiments, the key regions 220 may be configured to have fixed occupying areas that may be the same as each other, and the alignment key 225a with a large occupying area may be disposed on each of the key regions 220.

For example, as shown in FIGS. 4B through 4F, a plurality of alignment keys 225b to 225r may be disposed on one of the key regions 220 in various manners. For instance, three alignment keys 225b, 225c and 225d may be disposed on one of the key regions 220 as shown in FIG. 4B. Alternatively, two alignment keys 225e and 225f, as shown in FIG. 4C, or two alignment keys 225g and 225h, as shown in FIG. 4D, may be disposed on one of the key regions 220. Alternatively, four alignment keys 225i, 225j, 225k and 2251 may be disposed on one of the key regions 220 as shown in FIG. 4E, or six alignment keys 225m, 225n, 225o, 225p, 225q and 225r may be disposed on one of the key regions 220 as shown in FIG. 4F.

In some embodiments, each of the alignment keys to be used for the chip fabricating process may be one of the alignment keys 225b to 225r shown in FIGS. 4A through 4F. Moreover, each of the chip regions 210 in the shot groups 200 may have one of the alignment key configurations shown in FIGS. 4A through 4F. For instance, each of the six chip regions 210 in the shot groups 200 shown in FIG. 2 may include one key region 220, respectively, which may be configured to have one of the alignment key dispositions shown in FIGS. 4A through 4F. The alignment keys 225a to 225r may be used as fiducial marks in each of exposure processes in the chip fabricating process.

To form the semiconductor device on the chip regions 210, a plurality of exposure processes may be performed onto the shot groups 200. In some embodiments, the number of the exposure processes to be performed for forming the semiconductor device may be greater than or the same as the number of the alignment keys 225a to 225r. Each of the exposure processes may be performed using at least one of the alignment keys 225a to 225r in each of the chip regions 210. In some embodiments, each of the alignment keys 225a to 225r may be used for one of the exposure processes. For instance, when eighteen exposure processes are performed to form the semiconductor device on the chip regions 210, each of the eighteen exposure processes may be performed using the corresponding one of the alignment keys 225a to 225r.

Alternatively, each of the alignment keys 225a to 225r may be used for plural ones of the exposure processes different from each other. For instance, a first one (e.g., 225a) of the alignment keys 225a to 225r may be used for a first one of the exposure processes, a second one (e.g., 225b) of the alignment keys 225a to 225r may be used for a second one of the exposure processes, and the first one 225a of the alignment keys 225a to 225r may be repeatedly used for a third one of the exposure processes. As a result, the number of the alignment keys 225a to 225r may be less than the number of the exposure processes to be performed on the shot groups 200. According to the above example, the first one 225a of the alignment keys 225a to 225r may be repeatedly used for the distinct first and third ones of the exposure processes and the second one 225b of the alignment keys 225a to 225r may be used for the second one of the exposure processes. In certain embodiments, plural ones of the alignment keys 225a to 225r may not be used for each of the exposure processes.

In some embodiments, all of the alignment keys to be used for all of the exposure processes may be disposed on at least one of the key regions 220 or the chip regions 210 in each of the shot groups 200 and each of the key regions 220 or the chip regions 210 may include at least one of the alignment keys 225a to 225r. As the alignment keys 225a to 225r are disposed in the chip regions 210, the shot groups 200 may not need an additional area for disposing the alignment keys 225a to 225r. As a result, it is possible to reduce the ratio of a total occupying area of the shot groups 200 to the total area of the wafer 100.

According to an example embodiment of the inventive concept, one alignment key may be used to perform each of the exposure processes on each of the shot groups 200, while the exposure process may be performed on the wafer in units of the shot groups 200. Accordingly, it is possible to reduce the ratio of a total occupying area of the alignment keys 225a to 225r to the total area of the wafer 100. As a result, it is possible to increase the number of the chip regions 210 per the wafer 100 and to reduce a fabricating cost of the semiconductor chip.

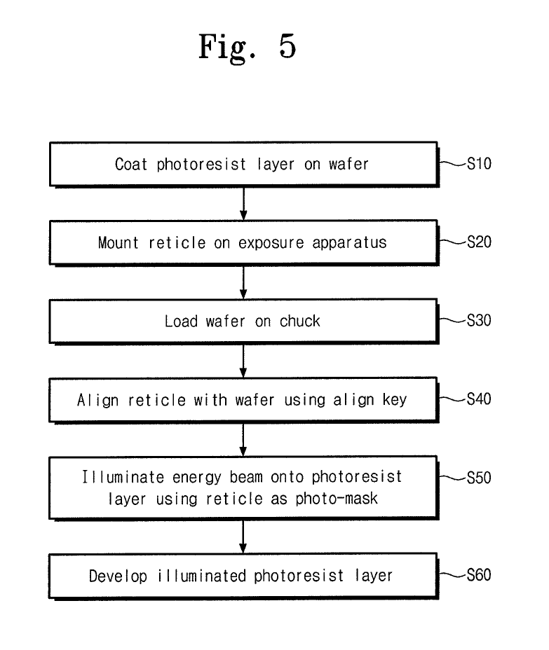

Hereinafter, an exposure process using the alignment keys according to an example embodiment of the inventive concept will be described with reference to the accompanying drawings. FIG. 5 is a flow chart illustrating an exposure process using alignment keys according to an example embodiment of the inventive concept.

Referring to FIGS. 1 and 5, a photoresist layer may be formed on a wafer 100 (in S10). The wafer 100 may include a plurality of shot groups 200, each of which includes alignment keys disposed based on an example embodiment of the inventive concept. The photoresist layer may be formed on the wafer 100 using, for example, a spin-coating process. The photoresist layer may include, for example, a carbon-containing polymer.

A reticle or a photomask may be mounted on an exposure apparatus (in S20).

The reticle may be configured to include, for example, reticle patterns, which will be transcribed onto the wafer 100 using the present exposure process. A transcription of the reticle patterns onto the wafer 100 may be performed in units of the shot group 200; that is, the reticle patterns may be disposed on the reticle in units of the shot group 200.

The wafer 100 provided with the photoresist layer may be loaded on a chuck of the exposure apparatus (in S30).

An alignment step aligning the reticle with the shot group 200 may be performed using one of alignment keys 225a to 225r, which may be included in the shot group 200 of the loaded wafer 100 (in S40). The alignment step may be performed to align an alignment key pattern, which may be one of the reticle patterns, and the alignment key formed on the shot group 200. At least one of the reticle or the chuck may be moved or rotated during the alignment step. As the result of the alignment step, the exposure process may be performed without a misalignment between electric components of the semiconductor device formed on the chip region 210.

An illumination step may be performed to illuminate an energy beam (e.g., a light beam or an electron beam) onto the aligned wafer 100 (in S50). The energy beam may pass through or be reflected by the mounted reticle, and then be projected onto the shot group 200 of the aligned wafer 100. As the result of the illumination step, the reticle patterns can be transcribed onto the shot group 200 of the wafer 100.

The alignment step of S40 and the illumination step of S50 may be performed on the wafer 100 in units of the shot group 200. That is, the alignment and illumination steps of S40 and S50 may be repeatedly performed until the reticle patterns are transcribed onto all of the shot groups 200 of the wafer 100. For instance, the exposure process may, at least, include a first alignment step of aligning the reticle with a first shot group 200 using an alignment key 225a to 225r included in the first shot group, a first illumination step of illuminating the energy beam onto the first shot group 200 via the reticle, a second alignment step of aligning the reticle with a second shot group 200 using an alignment key 225a to 225r included in the second shot group 200, and a second illumination step of illuminating the energy beam onto the second shot group 200 via the reticle. The second alignment step may further include moving the reticle to place the reticle over the second shot group 200 of the wafer 100.

After finishing the transcription of the reticle patterns onto all of the shot groups 200 of the wafer 100, a development step may be performed on the wafer 100 (in S60). As the result of the development step, portions of the photoresist layer, for example, exposed by the energy beam, may be removed to form photoresist patterns transcribed from the reticle patterns on the wafer 100.

According to example embodiments of the inventive concept, each of shot groups defined on a wafer may include a plurality of chip regions, each of which may include a key region. The key region may include at least one alignment key. As the alignment key is disposed on the chip region, the shot group may not need an additional area for disposing the alignment key. In addition, as the alignment keys are distributed on plural chip regions disposed in each of the shot groups, it is possible to reduce the area ratio of alignment keys to the chip region.

Due to the reduction of the occupying area of the alignment keys, it is possible to reduce the total area ratio of the shot groups to the wafer. As a result, it is possible to increase the number of the chip regions per the wafer and to reduce a fabricating cost of the semiconductor chip.

Having described example embodiments of the inventive concept, it is further noted that it is readily apparent to those of reasonable skill in the art that various modifications may be made without departing from the spirit and scope of the invention which is defined by the metes and bounds of the appended claims.

What is claimed is:

1. A method of disposing alignment keys, comprising:
preparing a substrate including a shot group, the shot group including a plurality of chip regions, wherein each of the chip regions includes a key region; and
forming at least one alignment key in each of the key regions of the substrate,
wherein each of the alignment keys is adapted to be used for at least one of a plurality of exposure processes which are different from each other, and
wherein center points of the key regions are located at points shifted from center points of the chip regions by a same distance along a same direction.

2. The method of claim 1, wherein the key regions in the shot group have substantially a same area as each other.

3. The method of claim 1, wherein the alignment keys disposed in the key regions have substantially a same width as each other in a specific direction.

4. The method of claim 1, wherein the forming of the alignment key further comprises forming a scribe lane between the chip regions.

5. The method of claim 4, wherein in a specific direction, a width of the scribe lane is less than a shortest width of at least one of the alignment keys.

6. A method of fabricating a semiconductor chip, comprising:
preparing a wafer including a shot group, the shot group including a plurality of chip regions, wherein each of chip regions includes a key region;
forming at least one alignment key in each of the key regions of the substrate; and
performing a plurality of exposure processes on the shot group to form semiconductor devices on the chip regions,
wherein each of the exposure processes is performed using one of the alignment keys formed in the key regions of the shot group.

7. The method of claim 6, wherein the plurality of the chip regions are defined by a scribe lane.

8. The method of claim 7, wherein in a specific direction, a distance between adjacent ones of the chip regions is less than a shortest width of at least one of the alignment keys.

9. The method of claim 8, further comprising dicing the wafer to separate the chip regions from each other, wherein the dicing of the wafer is performed between the chip regions adjacent to each other.

10. The method of claim 9, wherein the dicing of the wafer is performed using a laser.

11. The method of claim 6, wherein the key regions included in the chip regions have substantially a same area as each other.

12. The method of claim 6, wherein center points of the key regions are located at points shifted from center points of the chip regions by a same distance along a same direction.

13. The method of claim 6, wherein a number of the alignments keys is smaller than a number of the exposure processes for forming the semiconductor devices.

14. The method of claim 6, wherein a number of the alignment keys is equal to a number of the exposure processes for forming the semiconductor devices.

15. A method of fabricating a semiconductor chip:
preparing a wafer including a shot group, wherein the shot group includes a first chip region, a second chip region, a third chip region, a fourth chip region, a fifth chip region, and a sixth chip region disposed in two rows and three columns, wherein the first to sixth chip regions each include a key region, wherein center points of the key regions are located at points shifted from center points of the first to sixth chip regions by a same distance and along a same direction;
forming at least one alignment key in a respective one of each of the key regions of the first to sixth chip regions;
performing a plurality of exposure processes on the shot group to form semiconductor devices on the first to sixth chip regions, wherein each of the exposure processes is performed using one of the alignment keys formed in the key regions of the shot group and wherein at least two of the exposure processes are performed using a same one of the alignments keys; and
forming a scribe lane between each of the first to sixth chips regions, wherein the scribe lane has a width less than a first directional width or a second directional width of at least one of the alignment keys.

16. The method of claim 15, wherein only one alignment key is formed in a respective one of each of the key regions of the first to sixth chip regions.

17. The method of claim 15, wherein two alignment keys are formed in a respective one of each of the key regions of the first to sixth chip regions.

18. The method of claim 15, wherein three alignment keys are formed in a respective one of each of the key regions of the first to sixth chip regions.

19. The method of claim 15, wherein four or six alignment keys are formed in a respective one of each of the key regions of the first to sixth chip regions.

20. A method for performing an exposure process, comprising:
providing the substrate which includes the shot group, the chip regions, the key regions and the alignment keys formed according to claim 1;
forming a photoresist layer on the substrate which includes the chip regions, the key regions and the alignment keys;
mounting a reticle, which includes a plurality of reticle patterns on an exposure device;
loading the substrate including the photoresist layer formed thereon on a chuck of the exposure apparatus;
aligning the reticle with the shot group using one of the alignment keys included in the shot group of the substrate;
illuminating an energy beam onto the substrate in which the reticle has been aligned with the shot group to thereby transcribe the reticle patterns onto the shot group of the substrate; and
performing a developing step on the substrate to remove portions of the photoresist layer exposed by the energy beam to form photoresist patterns transcribed from the reticle patterns on the substrate.
